(19) United States
(12) Patent Application Publication
(10) Pub. No.: US 2013/0148271 A1
(43) Pub. Date: Jun. 13, 2013

(54) HANDSET PROTECTION HOUSING WITH FINGER RING

(71) Applicant: Feng-Dun Huang, Taipei Hsien (TW)

(72) Inventor: Feng-Dun Huang, Taipei Hsien (TW)

(21) Appl. No.: 13/323,834

(22) Filed: Dec. 13, 2011

(51) Int. Cl. H05K 5/00

(52) U.S. Cl. 361/679.01

(57) ABSTRACT

A handset protection housing with a finger ring includes a casing (1) includes a back plate (11) for holding a handset firmly; a near middle section of the back plate having a connection portion (10); a combining unit (2) being formed by soft or flexible material; the combining unit (2) being fixed to the connection portion of the back plate; the combining unit (2) having a ring-like structure for receiving a finger of a user, thereby, the user's finger can pass through the ring to hold the housing firmly.

### FIELD OF THE INVENTION

The present invention relates to handset protection cover, and in particular to a handset protection housing with a finger ring.

### BACKGROUND OF THE INVENTION

Handsets are more and more popular. Currently, there are many people who takes the handset all day long for talking or information receiving and transmission, even in eating, driving, working, and many daily works. it seems that many people can not live without handsets. However since the handsets are held long time in every day, it being possible that the handset fall down from the hand so as to be destroyed, even the hands can not work well. Therefore, protection casings are developed for protecting a handset from fall out of hand, but it is still possible that the handset slides out from the hand of the user due to the carelessness of the user.

Therefore, the inventor of the present invention desires to develop a novel design which can improve the above mentioned defect so as to provide a well protected casing which cause that the user can hold the handset firmly without sliding our of the hand.

### SUMMARY OF THE INVENTION

Therefore, the object of the present invention is to provide a handset casing with a finger ring by which, the user can hole the handset firmly and hole the handset by only one hand, while the user is not care about the falling down of the handset. Furthermore, since the fingers of the user can hole the handset firmly, even it plays game in the handset, the handset can still be turn over or turn to a desire direction, while the user does not need to care that the handset will slide out of the hand, meanwhile the fingers of the user still fell comfortable. Thus the present invention other than provides the function of housing a handset, but also the user can hold is firmly even in different operation poses.

To achieve above the present invention, the present invention provides a handset protection housing with a finger ring, comprising a casing (1) includes a back plate (11) for holding a handset firmly; a near middle section of the back plate having a connection portion (10); a combining unit (2) being formed by soft or flexible material; the combining unit (2) being fixed to the connection portion of the back plate; the combining unit (2) having a ring-like structure for receiving a finger of a user, thereby, the user's finger can pass through the ring to hold the housing firmly.

In one embodiment, the connection portion (10) is a long slit in the back plate of the casing; the combining unit (2) is a ring with a portion of the ring passing through the slit in the back plate so as to firmly secure to the back plate; in use, the finger of a user passes through the ring to be fixed therein and thus the user can hold the handset firmly in the casing.

In another embodiment, the connection portion (10) is formed by two slits or two holes; the combining unit is a strip; two ends of the strips pass through the two slits or two holes and then the two ends are combined. The two ends of the strip is tied together. Or the two ends of the strip are tied with respective Velcro stickers so that after passing through the two slits or two holes, the two ends can be combined by adhesion of the two Velcro stickers; and thus the strip out of the back plate will be formed as a ring. Or the two ends of the strip are installed with buttons. Or the two ends of the strip are installed with buckles.

Furthermore, the connection portion (10) is two slits or two holes 10, a recess portion (999) is formed with an area covering the two slits (or the two holes).

### BRIEF DESCRIPTION OF THE DRAWINGS

FIG. 1(A) is a perspective view of the present invention.

FIG. 1(B) shows the application in the first embodiment of the present invention.

FIG. 1(c) shows a cross sectional view of the casing in the first embodiment of the present invention.

FIG. 2(A) shows the connection portion of the casing in the second embodiment of the present invention.

FIG. 2(B) shows the connection portion and the connecting unit of the casing in the second embodiment of the present invention.

FIG. 2(C) shows the inner side of the FIG. 2(B).

FIG. 2(D) shows that the two ends of the combining unit are combined according to the present invention.

FIG. 3 shows another arrangement in the second embodiment of the present invention.

FIGS. 4(A), 4(B) and 4(C) show the third embodiment of the present invention.

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

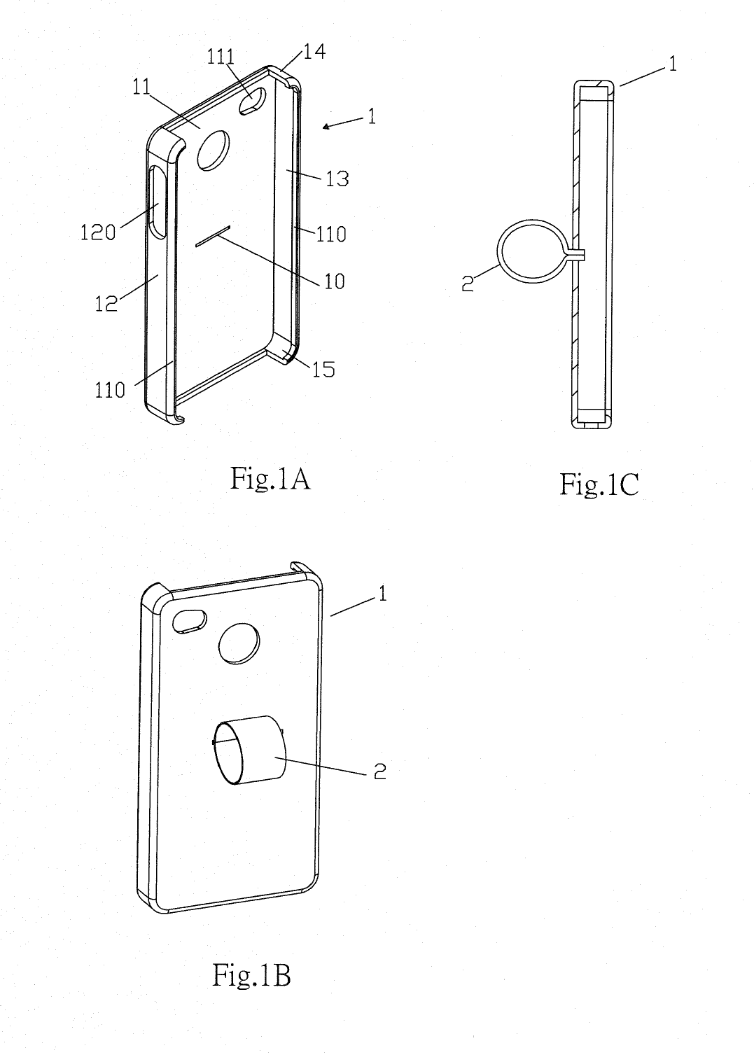

Referring to FIGS. 1 to 3, the structure of the present invention is illustrated. The present invention serves to provide a ring structure in a protection cover of a handset so that the finger of the user can insert through the ring to hold the cover firmly and thus the user will not care about that the handset will fall down from the hand so as to achieve the object of protecting the handset in a safe state. The present invention includes the following elements.

A casing 1 includes a back plate 11, a left plate 12 and a right plate 13 at a left and a right side of the back plate 11, respectively. A near middle section of the back plate has a connection portion 10. Each of the left plate 12 and the right plate 13 has a respective buckle 110. Each of the left plate 12 and the right plate 13 has an upper cambered edge 14 at an upper edge thereof and a lower cambered edge 15 at a lower edge thereof. The left plate 12 and right plate 13 serve to hold a handset therein. The left plate 12 or right plate 13 may be formed with through hole 120 for exposing the function key of a handset. The back plate 11 has a via hole 111 for exposing a camera lens of a handset.

A combining unit 2 is formed by soft or flexible material. The combining unit 2 is fixed to the connection portion 10 of the back plate 11. There are several ways for combining the combining unit 2 to the connection portion 10.

In the first embodiment for combining the combining unit 2 to the connection portion 10 is that: referring to FIG. 1(A), the connection portion 10 is a long slit 10 in the back plate 11 of the casing 1. The combining unit 2 is a ring (see FIG. 1(B)) with a portion of the ring passing through the slit 10 in the back plate 11 so as to firmly secure to the back plate 11 as the structure illustrated in FIG. 1(C). In use, the finger of a user passes through the ring 2 to be fixed therein and thus the user can hold the handset firmly in the casing 1. Preferably, the combining unit 2 is formed by nylon, or other fabrics.

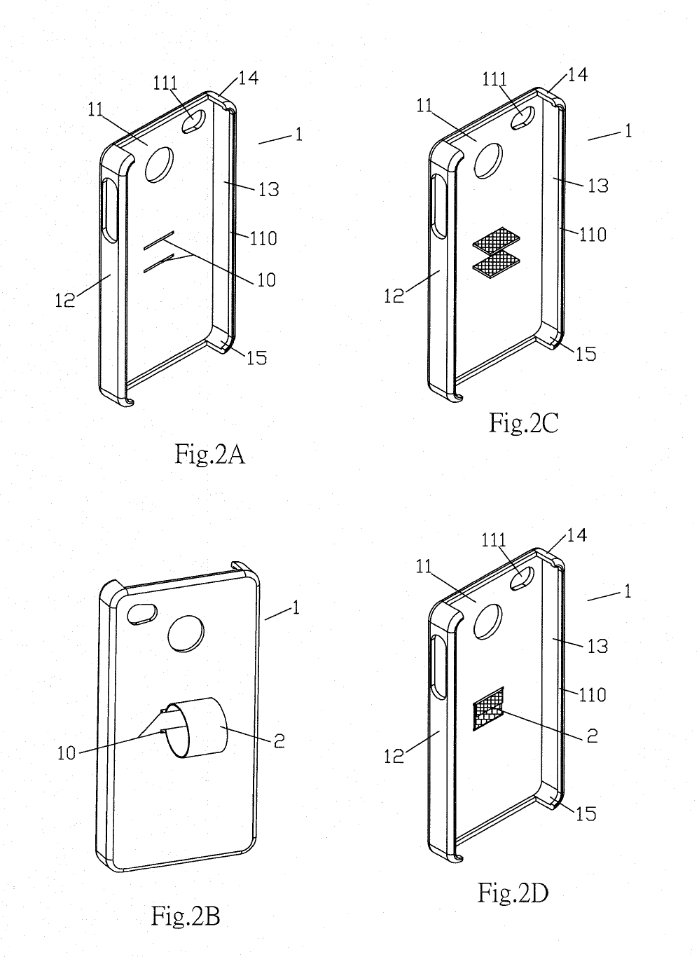

With reference to FIGS. 2(A), 2(B), 2(C) and 2(D), the second embodiment of the present invention is illustrated. In this embodiment, the connection portion 10 is formed by two slits. The combining unit 2 is a fabric strip. Two ends of the strip pass through the two slits and then the two ends are combined by many ways.

In a simplest case, the two ends can be tied together (not shown).

In another way, the two ends of the strip are tied with a Velcro sticker (see FIGS. 2(C) and 2(D)) so that after passing through the two slits 10, the two ends can be combined to the adhesion of the two Velcro stickers. Thus the strip out of the back plate 11 will be formed as a ring.

In using, the size of the ring form by the strip out of the back plate 11 is adjustable by adjusting the sticking position of the two Velcro stickers, causing the size of the ring to be suitable for the finger of user to hold the casing of the present invention.

Other than by installing Velcro stickers to the two ends of the strip, other combining objects are also suitable, such as buttons, or buckles are also suitable to be installed to the two ends of the strips.

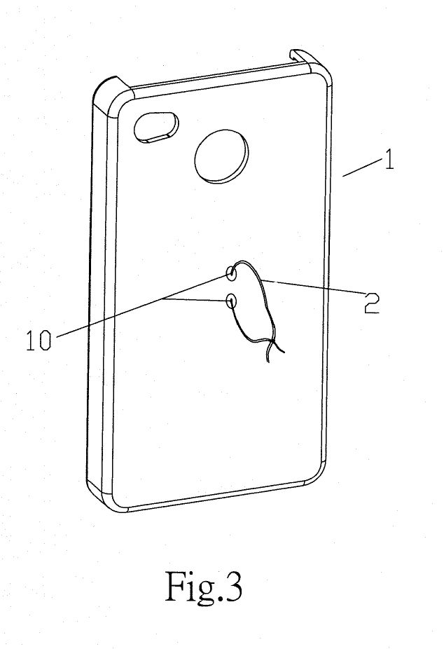

Furthermore, in this embodiment, as illustrated in FIG. 3, other than adapting slits as the connection portion 10, the connection portion 10 can be two holes so that the two ends of the strip can pass through the two holes.

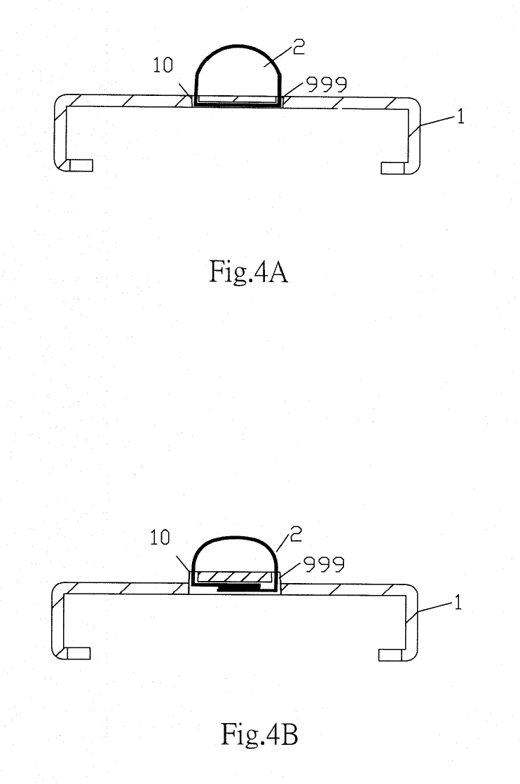

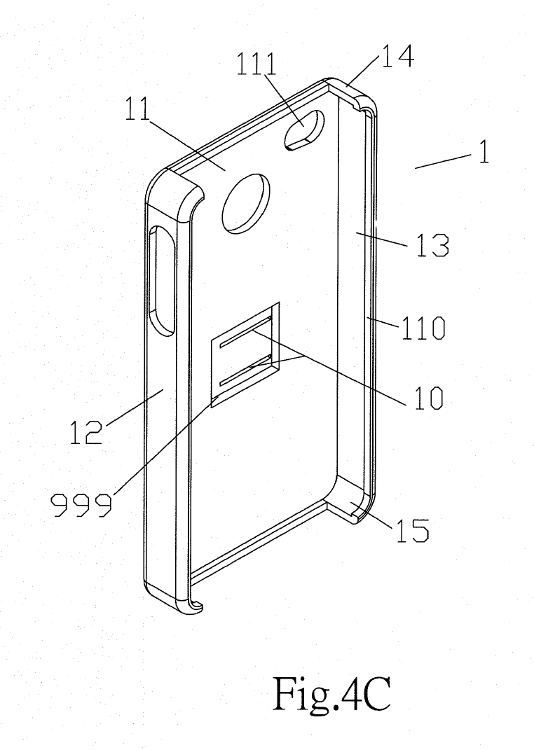

With reference to FIGS. 4(A), 4(B) and 4(C), the third embodiment of the present invention is illustrated. It is illustrated that the connection portion 10 is two slits or two holes 10, a recess portion 999 (viewing from the lower side of the back plate 10) is formed in an area covering the two slits (or the two holes) so as to form a recessed portion. FIG. 4(A) shows that the casing is thinned in the recess portion 999 and in FIG. 4(B), it shows that the recess portion still has the same thickness as other portion of the casing 1 so that as viewing from the outer side of the casing, it is illustrated that the portion 999 is a convex portion.

Referring to FIGS. 4(A), 4(B) and 4(C), the strip passing through the two holes 2 (the combining unit 2) and then passing the recess portion 999 so as to form a ring to cause a finger can pass through the ring for holding the casing 1 of the present invention. Due to the existence of the recess portion, the portion of the strip 2 on the recess portion 999 will not protrude out from the inner surface of the back plate 10 so as to present a flat appearance. When a handset is received in the casing 1, the casing 1 will flatly adhere to the housing of the handset.

The present invention provides a handset casing with a finger ring by which, the user can hold the handset firmly and hold the handset by only one hand, while the user is not care about the falling down of the handset. Furthermore, since the fingers of the user can hold the handset firmly, even it plays game in the handset, the handset can still be turned over or turned to a desire direction, while the user does not need to care that the handset will slide out of the hand, meanwhile the fingers of the user still feel comfortable. Thus the present invention other than provides the function of housing a handset, but also the user can hold is firmly even in different operation poses.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims

What is claimed is:

1. A handset protection housing with a finger ring, comprising:
a casing (1) includes a back plate (11) for holding a handset firmly; a near middle section of the back plate having a connection portion (10);
a combining unit (2) being formed by soft Of flexible material; the combining unit (2) being fixed to the connection portion of the back plate;
the combining unit (2) having a ring-like structure for receiving a finger of a user, thereby, the user's finger can pass through the ring to hold the housing firmly.

2. The handset protection housing with a finger ring as claimed in claim 1, wherein the casing includes the back plate (11), a left plate (12) and a right plate (13) at a left and a right side of the back plate 11, respectively; each of the left plate and the right plate has a respective buckle.

3. The handset protection housing with a finger ring as claimed in claim 2, wherein each of the left plate and the right plate has an upper cambered edge (14) at an upper edge thereof and a lower cambered edge (15) at a lower edge thereof; and the left plate and the right plate serve to hold a handset therein.

4. The handset protection housing with a finger ring as claimed in claim 3, wherein at lease one of the left plate and the right plate is formed with a through hole (120) for exposing the function key of a handset; and the back plate has a via hole (111) for exposing a camera lens of a handset.

5. The handset protection housing with a finger ring as claimed in claim 1, wherein the connection portion (10) is long slit in the back plate of the casing; the combining unit (2) is a ring with a portion of the ring passing through the slit in the back plate so as to firmly secure to the back plate; in use, the finger of a user passes through the ring to be fixed therein and thus the user can hold the handset firmly in the casing.

6. The handset protection housing with a finger ring as claimed in claim 5, wherein the combining unit is formed by nylon, or other fabrics.

7. The handset protection housing with a finger ring as claimed in claim 1, wherein the connection portion (10) is formed by two slits or two holes; the combining unit is a strip; two ends of the strips pass through the two slits or two holes and then the two ends are combined.

8. The handset protection housing with a finger ring as claimed in claim 7, wherein the two ends of the strip is tied together.

9. The handset protection housing with a finger ring as claimed in claim 7, wherein the two ends of the strip are tied with respective Velcro stickers so that after passing through the two slits or two holes, the two ends can be combined by adhesion of the two Velcro stickers; and thus the strip out of the back plate will be formed as a ring.

10. The handset protection housing with a finger ring as claimed in claim 7, wherein the two ends of the strip are installed with buttons.

11. The handset protection housing with a finger ring as claimed in claim 7, wherein the two ends of the strip are installed with buckles.

12. The handset protection housing with a finger ring as claimed in claim 7, wherein the connection portion (10) is two slits or two holes 10, a recess portion (999) is formed with an area covering the two slits (or the two holes).
